(19) United States
(12) Patent Application Publication
(10) Pub. No.: US 2007/0034156 A1
(43) Pub. Date: Feb. 15, 2007

(54) Method and apparatus for precision coating of molecules on the surfaces of materials and devices

(75) Inventors: Buddy D. Ratner, Seattle, WA (US); Frank Turecek, Seattle, WA (US); William T. Elam, Redmond, WA (US); Hak-No Lee, Edmonds, WA (US); Kathryn J. Kitching, Seattle, WA (US)

Correspondence Address: CHRISTENSEN, O'CONNOR, JOHNSON, KINDNESS, PLLC, 1420 FIFTH AVENUE, SUITE 2800, SEATTLE, WA, 98101-2347, US

(73) Assignee: Washington, University of, Seattle, WA (US)

(21) Appl. No.: 11/582,615

(22) Filed: Oct. 17, 2006

Related U.S. Application Data
(63) Continuation of application No. 10/081,990, filed on Feb. 20, 2002, now abandoned.

(51) Int. Cl. C23C 16/00

(52) U.S. Cl. 118/723 FI

(57) ABSTRACT

A method and apparatus for plasma treatment and deposition of ionized molecules on a surface of an object in a vacuum. The apparatus has a plasma treatment system including a plasma reactor chamber, an ion deposition system including an ion deposition chamber that is connected to the plasma reactor chamber, and a vacuum system for maintaining a vacuum in the chambers. The ion deposition system may include an ion guide chamber for guiding ionized molecule towards the target surface. A target guiding system moves the target surface between the plasma reactor chamber and the ion deposition chamber within the vacuum system through a gate, such that the target surface may be alternately subjected to plasma treatment and to deposition of ionized molecules without leaving the vacuum system.

### CROSS-REFERENCE TO RELATED APPLICATION

This application is a continuation of application Ser. No. 10/081,990 filed Feb. 20, 2002, priority from the filing date of which is hereby claimed under 35 U.S.C. §120.

### BACKGROUND OF THE INVENTION

1. Field of the Invention

The present invention is directed generally toward a method and apparatus for precision coating of molecules on the surfaces of materials and devices and specifically to the application of ionized molecules in the gas phase onto a plasma-treated surface.

2. Description of the Related Art

Electrospray ionization is used to inject very large molecules into mass spectrometers and can be used in air to fabricate thin films of large biomolecules while retaining their activity. Electrospray ionization can produce ionized molecules in the gas phase which can then be introduced into a vacuum system, where they can be manipulated via ion optics and deposited onto a surface. See, e.g., Cole, R. B. (Ed.), Electrospray Ionization Mass Spectrometry, Wiley, N.Y. (1997); Matsuo, T., et al., J. Mass Specrom, 35, 114-130 (2000); Morozova, T., et al., Anal. Chem. 71, 1415-1420 (1999). Very large molecules, such as molecules of 100 kiloDaltons to 1 megaDalton, can be transported into the gas phase using solution electrospray. This includes molecules that decompose at temperatures below the vaporization temperature, such as enzymes and large sugars, including hyaluronic acid. Smaller molecules may also be transported into the gas phase using solution electrospray.

Other sources for generating ionized molecules in the gas phase include Atmospheric Pressure Chemical Ionization (APCI), Fast-Atom Bombardment (FAB), modified FAB sources, including Liquid Secondary Ion Mass Spectrometry (LSIMS) and Continuous FAB sources, and Matrix-Assisted Laser Desorption Ionization (MALDI). Ionized molecules in the gas phase produced by such methods can also be introduced into a vacuum system, manipulated via ion optics, and deposited onto a surface. It is difficult and not always possible, however, to achieve the desired density of molecules on the surface of an object with conventional technologies.

Plasma treatments provide a diverse range of surface modification possibilities and are environmentally friendly and economical in their use of materials. Plasma treatment has the following features that are by no means mutually exclusive. Plasma treatment can be used to breakdown surface oils and loose contaminates. For metal surfaces, plasma treatment can leave the surface truly “cleaned” down to the base metal. However, using a number of plasma parameters reactive functionalities or dangling bonds may be obtained in a wide variety of substrate materials. Plasma treatment also permits micro-roughening of a surface. Surface conditions can also be altered by the substitution or addition of new chemical groups from the active species created in the plasma. Process gases such as O₂, N₂, He, Ar, NH₃, N₂O, CO₂, CF₄ and air or some combination thereof are most commonly used for activation purposes, although a host of others may be successfully utilized.

Plasma treatment can also be used to deposit other materials onto surfaces, such as thin polymeric films. See Ratner, B., Ultrathin Films (by Plasma Deposition), 11 Polymeric Materials Encyclopedia 8444-8451 (1996). Polymers are very large molecules created when many smaller links of monomer molecules are joined. Plasma treatment can create polymer films from materials that do not form polymers by conventional wet chemistry techniques. The surface can be coated with polymeric substances of controlled molecular weight, chemical polarity or other reactivity. Plasmas can fractionate feed gases without linkable sites into a variety of new and reactive compounds that may subsequently polymerize. Structure in plasma polymers can be varied by, inter alia, using co-reactants or introducing O₂, N₂ or NH₃ into the reaction chamber during polymerization to incorporate specific atomic species. See Schram, D., et al., 62 Polymeric Mat. Sci. Eng. 25 (1990). See also Smolinsky, G., Symposium on Plasma Chemistry of Polymers p. 105, edited by M. Shen (Marcel Decker, Inc., New York, 1976). Plasma treatment is an effective surface treatment for different sample shapes, sizes, materials, and geometries.

It can be appreciated that there is a significant need for an improved system and method for depositing ionized molecules onto a surface. The present invention provides this and other advantages, as will be apparent from the following detailed description and accompanying figures.

### BRIEF SUMMARY OF THE INVENTION

The present invention is embodied in a method and apparatus for depositing ionized molecules in a gas phase, such as large biomolecules, onto a surface and for plasma-treating the surface. In one embodiment, the method comprises transferring ionized molecules to a vacuum, plasma-treating the surface in the vacuum, and controlling the deposition of the ionized molecules on the surface in the vacuum. In that embodiment, the apparatus may comprise a vacuum system comprising a plasma treatment system, an ion deposition system, which may comprise ion guiding optics, to guide the ionized molecules to the target surface, and a target guiding system, to position a target surface in the ion guiding system and the plasma treatment system.

### BRIEF DESCRIPTION OF THE SEVERAL VIEWS OF THE DRAWING(S)

FIG. 1 is a functional block diagram of one embodiment of an apparatus for implementing the present invention.

FIG. 2 is a functional block diagram of an embodiment of an apparatus for implementing the present invention employing an electrospray injector system to provide a source of ionized molecules.

FIG. 3 is a functional block diagram for an electrospray injector system for use in one embodiment of the present invention.

FIG. 4 is a flow chart illustrating the operation of one embodiment of the present invention.

FIG. 5 is a cross-sectional view of a surface treated by a method embodying the present invention.

FIG. 6 is a cross-sectional view of another surface treated by a method embodying the present invention.

### DETAILED DESCRIPTION OF THE INVENTION

The present invention is embodied in a method and apparatus for depositing ionized molecules in a gas phase, such as large biomolecules, onto a surface of an object and for plasma-treating the surface.

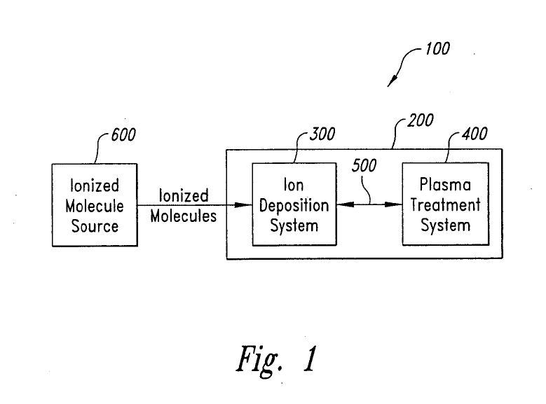

The present invention is embodied in an apparatus 100 illustrated in the functional block diagram of FIG. 1. The apparatus 100 includes a vacuum system 200, an ion deposition system 300, a plasma treatment system 400 and a target guiding system 500. The apparatus may also include an ionized molecule source 600 to provide ionized molecules of the desired type, such as ionized hyaluronic acid or ionized enzymes, to the ion deposition system 300, which is contained within the vacuum system 200.

Sources of ionized molecules are well known in the art and include the following: Electrospray Injection; Atmospheric Pressure Chemical Ionization (APCI); Fast-Atom Bombardment (FAB); Liquid Secondary Ion Mass Spectrometry (LSIMS); Continuous FAB; and Matrix-Assisted Laser Desorption Ionization (MALDI). Ionized molecules can be produced from various sources, such as solutions of biopolymers, and can be singly or multiply charged cations and/or anions. Production of ionized molecules is not the subject of this invention and thus, with the exception of a description of a particular electrospray injection system used in an embodiment of the invention for purposes of illustration, need not be discussed in detail herein. After reviewing the specification, one of skill in the art would be able to select an appropriate source for the desired ionized molecules with little or no experimentation. For example, one of skill in the art might consider using an APCI source if it was desired to deposit ionized esters or ketones on the surface of an object, as APCI is known in the art to produce ionized esters and ketones. One of skill in the art will also recognize that the ionized molecule source 600 may utilize ion optics and other techniques to facilitate the providing of ionized molecules to the ion deposition system 300 in the vacuum system 200.

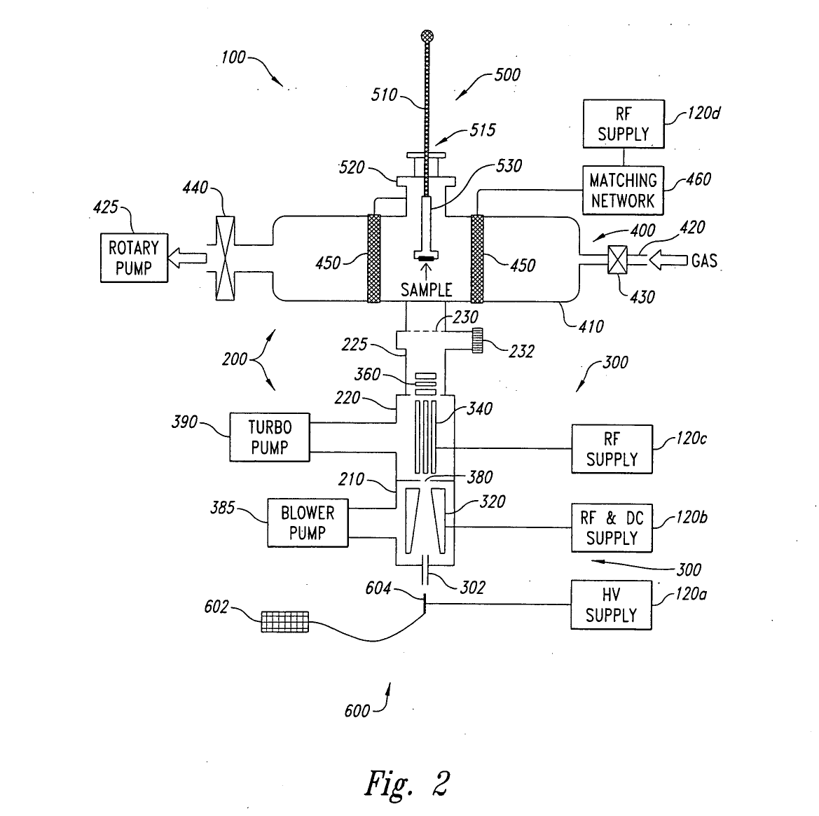

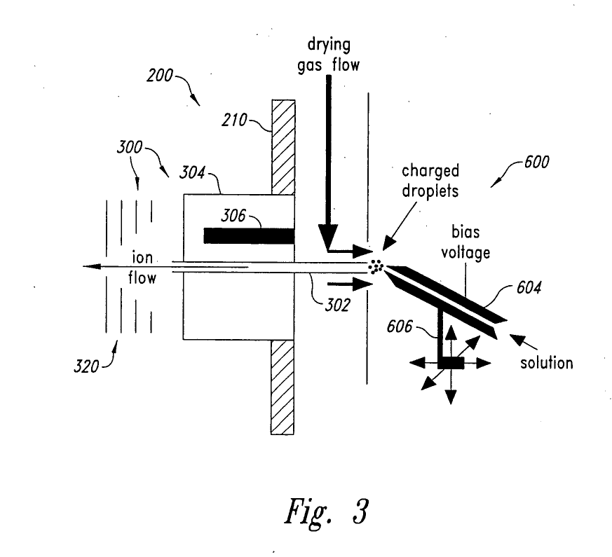

FIGS. 2 and 3 illustrate an electrospray ionization system suitable for use as the ionized molecule source 600 for the ion deposition system 300. A syringe pump 602 pumps a solution through a spray capillary 604. The solution will typically contain the desired molecules and a solvent. Commercially available syringe pumps capable of low flow rates, such as the Fisher KDS-100, and equivalents will perform satisfactorily as the syringe pump 602. A stainless steel capillary of approximately 0.25 mm inner diameter which is tapered approximately 30° to a point at the spray end will perform as the spray capillary 604. One of skill in the art will recognize that equivalent spray mechanisms may be used. An inlet capillary 302 is positioned near the spray capillary 604 to transfer ionized molecules to the ion deposition system 300. A glass-lined stainless steel capillary with an inner diameter of 0.8 mm and a length sufficient penetrate the vacuum system wall will function appropriately as an input capillary 302. Spacing of the spray capillary 604 with respect to the inlet capillary 302 impacts the performance of the apparatus 100. Accordingly, the spray capillary 604 can be placed on a multi-coordinate manipulator, such as an XYZ manipulator 606, to facilitate control of the distance and positioning.

The apparatus 100 has a power supply system 120 to supply various RF and DC voltages required by the components of the apparatus 100. A bias voltage of a relatively large value is generated by the power supply system 120a and applied to the spray capillary 604 with respect to the inlet capillary 302. The high voltage components of the power supply system 120 should be able to recover from occasional discharges and arcs. In testing, the commercially available Bertan Model 230-05R performed in a satisfactory manner. After reviewing this specification, one of skill in the art could select appropriate commercially available components for the power supply system 120. The bias voltages should be positive or negative, depending on the characteristics of the molecules to be ionized. For the embodiment illustrated in FIGS. 2 and 3, satisfactory ionization occurs when a voltage of plus or minus approximately 1000 volts DC is applied to the spray capillary 604 and a voltage of plus or minus approximately 500 volts DC is applied to the inlet capillary 302. The spray capillary 604 may be electrically isolated by an insulator (not shown) such as 50 mm ceramic standoff insulator.

The inlet capillary 302 may be mounted in a capillary mounting block 304 (see FIG. 3) in a chamber wall 210 of the vacuum system 200. The capillary mounting block 304 may contain a heater 306 (such as the commercially available Scientific Instrument Services 3618K421). Typically; the inlet capillary 302 may be heated to approximately 100° C. Drying gas, such as nitrogen, flows past the heater 306 and in the opposite direction of the charged droplets emerging from the spray capillary 604, which are carried by the electric field to the inlet capillary 302. The use of drying gas helps to reduce the amount of solvent contained in the spray mixture which is sucked into the vacuum system 200 and provides a clean gas to be sucked into the vacuum system 200. The amount of flow may be measured by a variable area flow gauge (such as a Cole-Palmer U-32458-50) (not shown). The ionized molecule source 600, which as shown in FIGS. 2 and 3 as an electrospray injection system, may be covered by an insulating shield (not shown) with an interlock switch (not shown) to the power supply system 120, to improve the safety of the apparatus 100.

In the embodiment shown in FIG. 2, the ion deposition system 300 comprises an inlet capillary 302, an ion funnel 320, a multipole ion guide 340, electrostatic lenses 360 (such as deflection and Einzel lenses), an aperture 380, and pumps 385, 390. The ion deposition system 300 guides ionized molecules to the surface of the object on which it is desired to deposit ionized molecules. As discussed in more detail below, the ion deposition system 300 may also remove solvents and undesired gases. The ion deposition system 300 shown in FIG. 2 may be configured to guide the ions to specific locations on the surface of the object. Thus, when used in combination with the target guiding system 500, it is possible to deposit ionized molecules in patterns on the surface of the object with the ion deposition system 300. Additional ion guides, lenses, and apertures, as well as magnetic fields, may be employed to fine-tune the ability of the ion deposition system 300 to guide ionized molecules to specific surfaces on an object. Further, the ion current can be measured to determine the amount of material deposited on the surface of the object.

The ion funnel 320 may consist of a radio frequency funnel lens, such as the lens disclosed in U.S. Pat. No. 6,107,628. Another ion funnel design is disclosed by Lynn, E. C., et al[.?], 14 Rapid Comm. Mass. Spectrom 2129-2134 (2000). Ion funnels are known in the art. After reviewing this specification, one skilled in the art would be able to design or select an appropriate ion funnel 320 with little or no experimentation. Although not required for the present invention, use of an ion funnel 320 is useful because it facilitates achieving high ionized molecule transmission rates.

In the embodiment shown in FIG. 2, a DC gradient applied along the ion funnel 320 propels ionized molecules toward the small end of the ion funnel 320. An RF voltage applied along the ion funnel 320 produces an effective radial potential, which moves the ions toward the axis of the ion funnel 320. As the ionized molecules are swept through the ion funnel 320 by the DC potential, they collide with background gas molecules and lose kinetic energy. As a result the ionized molecules arrive at the end of the ion funnel 320 with relatively low momentum. The energy level of the ionized molecules may be increased if desired by applying a bias voltage to the surface of the object. The vacuum chamber 210 containing the ion funnel 320 is pumped by a blower pump 385, which maintains the vacuum against the conductance of the inlet capillary 302. The pumping also helps to remove solvent and dry gases. Additional differential pumping of the vacuum system 200 can be employed to remove additional solvent and dry gas from the apparatus 100.

An aperture 380 follows the ion funnel 320, with the axis of the aperture 380 aligned with the axis of the ion funnel 320. The aperture 380 facilitates differential pumping and may be biased to continue the DC potential gradient in the ion funnel 320. The aperture 380 can also be biased to collect the current emerging from the ion funnel 320 to allow the funnel operating parameters to be optimized. The outlet side of the aperture 380 is aligned with the axis of the multipole ion guide 340. The ion guide 340 may be operated in RF-only mode. The RF voltage on the ion guide 340 serves to confine the ions to the center of the multipole ion guide 340. A DC potential could also be applied to the multipole ion guide 340, either in combination with an RF potential or as an alternative to the RF potential.

The surface (identified as a sample in FIG. 2) on which ionized molecules are to be deposited is placed close to the exit of the multipole ion guide 340 when it is desired to deposit ionized molecules on the surface of the object. A distance of less than 2 mm will help to minimize the impact of stray electric and magnetic fields. A holder comprised of a suitable material (not shown) may be placed in front of the ion guide 340 to promote accurate alignment of the surface with the axis of the multipole ion guide 340. The vacuum in the ion guide chamber 220 is maintained by a turbo pump 390. The pumping helps to remove solvent and dry gas. The ends of the multipole ion guide 340 may protrude slightly from the ion guide chamber 220 into the ion deposition chamber 225 to facilitate positioning the sample surface close to the exit of the multipole ion guide 340. The multipole ion guide 340 may be an octapole ion guide.

In the embodiment shown in FIG. 2, an ion deposition chamber 225 is between the ion guide chamber 220 and a plasma reactor chamber 410. The ion deposition chamber 225 may be closed-off from the plasma reactor chamber 410 through the use of a gate 230 operable by a gate valve 232.

The plasma treatment system 400 of the embodiment of the apparatus 100 shown in FIG. 2 is similar to those described in Ratner, B. D., “Ultrathin Films by Plasma Deposition”, in Polymeric Materials Encylcopedia, Volume 11, Joseph C. Salamone, Ed., CRC Press, Boca Raton, 1006, and comprises the plasma reactor chamber 410 with a gas inlet 420 at one end and rotary vacuum pump 425 at the opposite end. The inlet gas flow is controlled by a mass flow controller 430. The pressure is measured by a capacitance manometer (not shown) and regulated to a preset value by a throttle valve 440. Typical values of the flow and pressure are 10 sccm and 250 mTorr, respectively. The tuning of the throttle valve 440 is not critical and the factory values may be used. The use of flexible couplings, such as metal bellows (not shown) will prevent strain on the plasma reactor chamber 410 which may be made of glass. A cold trap (not shown) to trap volatile gasses and a burst disk (not shown) to prevent over-pressurization of the plasma reactor chamber 410 may also be present in the vacuum system for the plasma treatment system 400. The rotary vacuum pump 425 for the plasma treatment system 400 may contain an appropriate lubricant to avoid damage from pumping oxygen. The plasma is generated by applying a radio frequency signal from the power supply system 120d through a matching network 460 to a plurality of electrodes 450 in the plasma reactor chamber 410. The electrodes 450 may be arranged in various geometries to obtain the desired plasma characteristics.

Although the embodiment shown in FIG. 2 illustrates a plasma treatment system 400 employing a RF plasma generator, other plasma generators may be used, including audio frequency, microwave and direct current plasma generators.

The target guiding system 500 moves the target surface 90 between the plasma treatment system 400 and the ion deposition system 300 within the vacuum system 200. In the embodiment shown in FIG. 2, the target guiding system 500 moves the target 90 between the plasma reaction chamber 410 and the ion deposition chamber 225 and properly positions the target surface 90 in the appropriate chamber. Thus, the target guiding system 500 allows the target surface 90 to be alternately subjected to plasma treatment and to deposition of ionized molecules without leaving the vacuum system 200. The target guiding system may comprise a positioning member operable to position the surface of the object to be treated. For example, mechanical motors (not shown) could be employed to position the object in response to control commands.

In the embodiment shown in FIG. 2, the target guiding system 500 comprises a glass tube 510 which enters the plasma reactor chamber 410 through an o-ring fitting 515 in a kwik-flange port 520. The o-ring fitting 515 allows the glass tube 510 to slide along its length, thus moving the target surface 90 as necessary. The glass tube 510 is capped with a glass to metal seal with a threaded cap (not shown). A ceramic sample holder 530 screws onto the cap, allowing various sized objects and mounting mechanisms to be utilized.

A cable (not shown) can be slid inside the tube 510 to make contact with the sample holder 530, or the target surface 90 can be left floating. This provides for flexibility in arranging the geometry of the plasma electrodes 450 to achieve the desired plasma configuration without interference from the cable while still providing for measurement of the sample current during deposition of ionized molecules. The kwik flange port 520 allows for easy changing and repositioning of the object whose surfaces are to be treated by the apparatus.

After reviewing this specification, one of skill in the art will recognize that the apparatus 100 and method illustrated in FIG. 2 may be modified with little or no experimentation to accommodate objects of different shapes and sizes and with different properties and to achieve specific coating characteristics. For example, ion optics can be employed to control or steer the trajectories of the ionized molecules, if spatial control of a spot on the target on which ionized molecules are to be deposited is desired. Additional manipulation of the object can be employed, such as rotation of the object. Movement of the object in conjunction with the steering or focusing of the ion trajectory permits coating of the surface of an object in a specific pattern, if desired. Multiple coatings may be applied and the object may be subjected to multiple plasma treatments. Additional differential pumping can be employed to permit introduction of an object from the ambient atmosphere into the apparatus for processing and removal to the ambient atmosphere after processing, such as an air-to-vacuum-to-air interface. These modifications may be particularly useful for medical devices with a porous, irregular design, such as vascular grafts, stents, sutures and other devices used in interventional medical procedures. In addition, the ion optic and differential pumping configurations can be modified to increase the ability to separate solvents, if increased purity of the deposited material is desired.

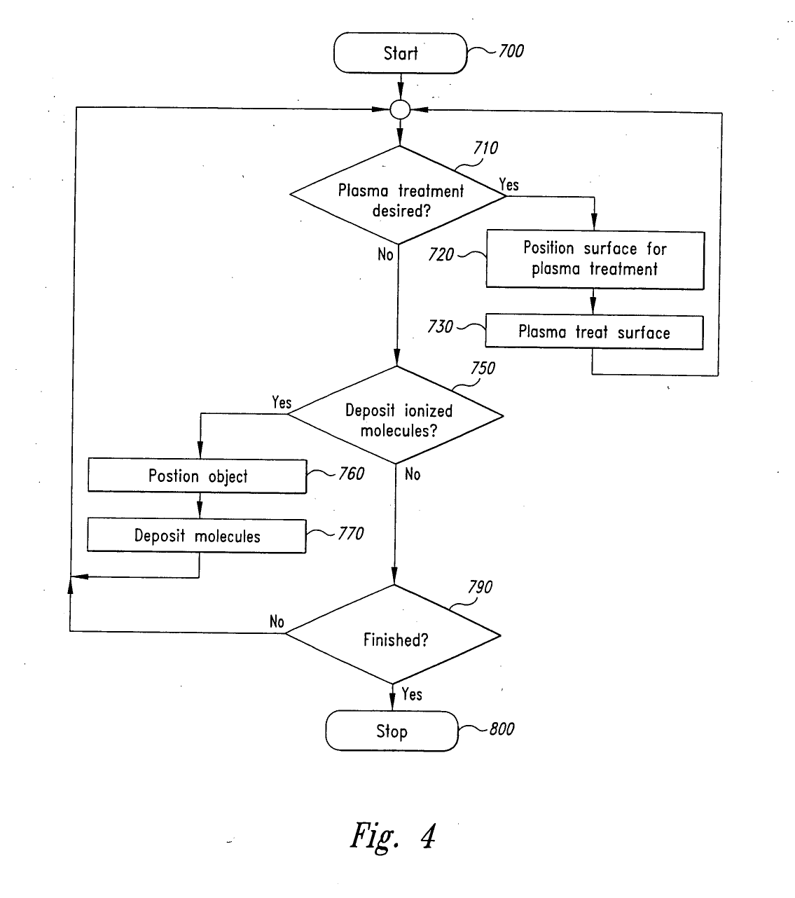

FIG. 4 is a flow chart illustrating operation of an embodiment of the present invention. At a start 700 the apparatus is initialized. At step 710, it is determined whether plasma treatment is desired. If the answer at step 710 is YES, the surface is positioned for plasma treatment in step 720 followed by plasma treatment in step 730. The apparatus then returns to step 710 for further processing if desired.

If the answer at step 710 is NO, the apparatus proceeds to step 750, where it is determined whether deposition of ionized molecules is desired. If the answer at step 750 is YES, the surface is position for deposition of ionized molecules in step 760 and ionized molecules are deposited in step 770. The apparatus then returns to step 710 for further processing if desired.

If the answer at step 750 is NO, the apparatus proceeds to step 790, where it is determined whether processing of the object is finished. If the answer at step 790 is YES, processing is stopped at step 800. If the answer at step 790 is NO, the apparatus returns to step 710 for further processing if desired.

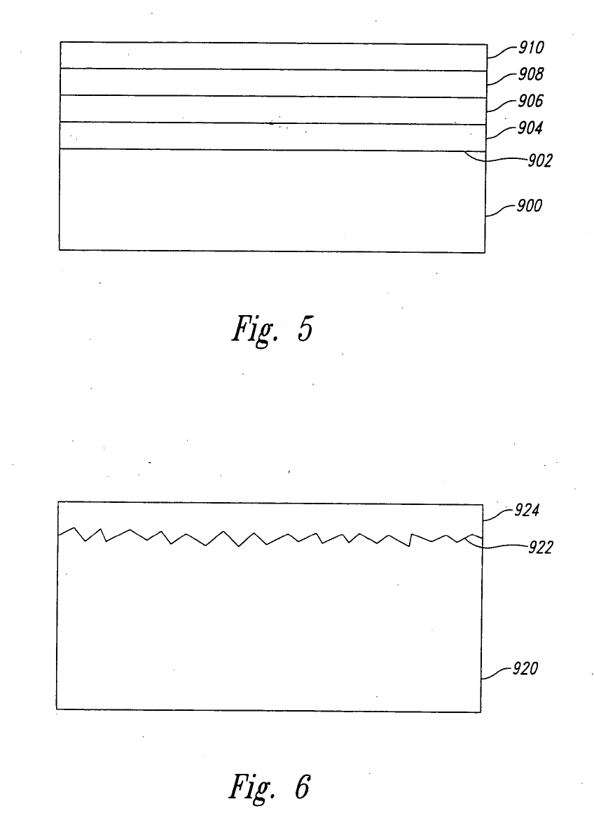

FIG. 5 illustrates an embodiment of an object 900 prepared using an embodiment of the method of the present invention. Layer 904 comprises ionized molecules deposited on a surface 902 of the object 900. Layer 906 comprises a polymer layer deposited in plasma treatment on the surface 902 of the object 900. Layer 908 comprises a second polymer layer deposited in plasma treatment. Layer 910 comprises an additional layer of ionized molecules deposited on the surface 902 of the object 900. Thus, as FIG. 5 illustrates, multiple layers may be deposited on a surface 902 of a object 900 and plasma treatment and ionized molecule deposition can occur in various sequences.

FIG. 6 illustrates another embodiment of a object 920 treated using an embodiment of the method of the present invention. A surface 922 of the object was micro-roughened using plasma treatment. Then a layer 924 of ionized molecules was deposited on the plasma treated surface 922.

From the foregoing it will be appreciated that, although specific embodiments of the invention have been described herein for purposes of illustration, various modifications may be made without deviating from the spirit and scope of the invention. In addition, after having reviewed this specification, one of skill in the art would be able to ascertain suitable substitutes for the specific examples of equipment referred to in the specification. Accordingly, the invention is not limited except as by the appended claims.

1. (canceled)

2. An apparatus for depositing ionized molecules onto a deposition target comprising:
a source of ionized molecules;
an ion guide apparatus;
a deposition vacuum chamber substantially enclosing the ion guide apparatus;
a first pump operably connected to the deposition vacuum chamber, and adapted to produce a vacuum in the deposition vacuum chamber;
an aperture through the deposition vacuum chamber for introducing ionized molecules from the source of ionized molecules into the deposition vacuum chamber;
a plasma generator;
a plasma reactor chamber substantially enclosing the plasma generator, the plasma reactor chamber being attached to the deposition vacuum chamber;
a passage fluidly connecting the deposition vacuum chamber to the plasma reactor chamber;
a second pump operably connected to the plasma reactor chamber and adapted to produce a vacuum in the plasma reactor chamber; and
a target guidance system adapted to move a deposition target through the passage between the plasma reactor chamber and the deposition vacuum chamber.

3. The apparatus of claim 2, wherein the plasma generator comprises a plurality of electrodes, and further comprising an RF power supply operably connected to the plurality of electrodes through a matching network.

4. The apparatus of claim 2, further comprising a gate valve disposed in the passage for selectively opening and closing the passage.

5. The apparatus of claim 2, wherein the ion guide apparatus comprises a multipole ion guide.

6. The apparatus of claim 5, wherein the ion guide apparatus further comprises an ion funnel.

7. The apparatus of claim 6, wherein the deposition vacuum chamber comprises a first portion enclosing the ion funnel and a second portion enclosing the multipole ion guide, the first and second portions being fluidly connected through an aperture.

8. The apparatus of claim 7, further comprising a third pump, and wherein the first pump is operably connected to the first portion of the deposition vacuum chamber and the third pump is operably connected to the second portion of the deposition vacuum chamber.

9. The apparatus of claim 5, wherein the ion guide apparatus further comprises an electrostatic lens.

10. The apparatus of claim 2, wherein the target guidance system comprises a sample holder adapted to retain the deposition target, and an elongate member attached to the sample holder, wherein the elongate member slidably extends through the plasma reactor chamber such that the deposition target is movable between the plasma reactor chamber and the deposition vacuum chamber.

11. The apparatus of claim 2, wherein the source of ionized molecules comprises a pump adapted to pump a solution through a spray capillary, and further wherein the spray capillary is attached to a multi-coordinate manipulator.

12. An apparatus for depositing ionized molecules onto a deposition target comprising:
a source of ionized molecules;
means for guiding ionized molecules from the source of ionized molecules;
a deposition vacuum chamber substantially enclosing the means for guiding ionized molecules;
means for generating a plasma;
a plasma reactor chamber substantially enclosing the means for generating a plasma, wherein the plasma reactor chamber fluidly engages the deposition vacuum chamber through a passage;
a vacuum system for generating a vacuum in the deposition vacuum chamber and in the plasma reactor chamber; and
means for moving a deposition target through the passage between the plasma reactor chamber and the deposition vacuum chamber without the deposition target leaving the vacuum system.

13. The apparatus of claim 12, wherein the means for generating a plasma comprises a plurality of electrodes, and wherein the plurality of electrodes are connected to an RF power supply through a matching network.

14. The apparatus of claim 12, wherein the vacuum system comprises a first pump adapted to evacuate the plasma reactor chamber, and a second pump adapted to evacuate the deposition vacuum chamber.

15. The apparatus of claim 14, wherein the deposition vacuum chamber comprises a first portion enclosing the ion funnel and a second portion enclosing the multipole ion guide, the first and second portions being fluidly connected through an aperture.

16. The apparatus of claim 15, further comprising a third pump, and wherein the second pump is operably connected to the first portion of the deposition vacuum chamber and the third pump is operably connected to the second portion of the deposition vacuum chamber.

17. The apparatus of claim 12, wherein the means for guiding ionized molecules includes a mulitpole ion guide.
